(19) United States
(12) Patent Application Publication
(10) Pub. No.: US 2025/0048765 A1
(43) Pub. Date: Feb. 6, 2025

(54) DISPLAY PANEL

(71) Applicant: AUO Corporation, Hsinchu (TW)

(72) Inventors: Shih-Hua Lu, Hsinchu (TW); Tzu-Hsuan Yang, Hsinchu (TW); Chao-Chien Chiu, Hsinchu (TW)

(73) Assignee: AUO Corporation, Hsinchu (TW)

(21) Appl. No.: 18/537,761

(22) Filed: Dec. 12, 2023

(30) Foreign Application Priority Data
Aug. 1, 2023 (TW) 112128763

(51) Int. Cl. H01L 27/146; G02B 3/00; H01L 31/0216

(52) U.S. Cl. CPC H01L 27/14627; G02B 3/0056; H01L 31/02164

(57) ABSTRACT

A display panel including a circuit substrate, a plurality of light-emitting elements, a plurality of microlenses, and a plurality of dummy microlenses is provided. The circuit substrate is provided with a plurality of pixel areas. Each of the pixel areas is provided with the light-emitting elements. The plurality of microlenses are disposed on the circuit substrate and respectively overlapped with the light-emitting elements. The plurality of dummy microlenses are disposed between the microlenses and not overlapped with the light-emitting elements.

### CROSS-REFERENCE TO RELATED APPLICATION

This application claims the priority benefit of Taiwan application serial no. 112128763, filed on Aug. 1, 2023. The entirety of the above-mentioned patent application is hereby incorporated by reference herein and made a part of this specification.

### BACKGROUND OF THE INVENTION

### Field of the Invention

The invention relates to a display technique, and in particular to a display panel.

### Description of Related Art

LED displays are gradually gaining popularity in the market due to their high color saturation, fast response speed, and high-contrast optical performance. In particular, micro LED displays have development advantages due to their low energy consumption and long material service life. In order to improve the light output efficiency of the micro LEDs, after the micro LEDs are transferred and bonded to the circuit substrate, microlenses are disposed at a side of the light exit surface thereof to change the light output field pattern thereof. However, when the arrangement spacing of micro LEDs is increased, the vacant areas between the plurality of microlenses overlapped with the plurality of micro LEDs are expanded, so that the curvature radius of the microlenses are varied too much after the manufacturing process, thus affecting the overall light output uniformity and light output efficiency.

### SUMMARY OF THE INVENTION

The invention provides a display panel having both better light output efficiency and uniformity.

A display panel of the invention includes a circuit substrate, a plurality of light-emitting elements, a plurality of microlenses, and a plurality of dummy microlenses. The circuit substrate is provided with a plurality of pixel areas. Each of the pixel areas is provided with the light-emitting elements. The plurality of microlenses are disposed on the circuit substrate and respectively overlapped with the light-emitting elements.

The plurality of dummy microlenses are disposed between the microlenses and not overlapped with the light-emitting elements.

Based on the above, in the display panel of an embodiment of the invention, the microlenses disposed overlapped with the light-emitting elements may effectively improve the light output efficiency of the light-emitting elements. By disposing the plurality of dummy microlenses in the area around the microlenses without being overlapped with the light-emitting elements, the variation in the curvature radius of the microlenses after the manufacturing process may be effectively reduced.

### BRIEF DESCRIPTION OF THE DRAWINGS

FIG. 1 is a schematic front view of a display panel according to the first embodiment of the invention.

FIG. 2 is a schematic cross-sectional diagram of the display panel of FIG. 1.

FIG. 3 is a schematic front view of another variant embodiment of the display panel of FIG. 1.

FIG. 4 is a schematic front view of a display panel according to the second embodiment of the invention.

FIG. 5 is a schematic cross-sectional diagram of the display panel of FIG. 4.

FIG. 6 is a schematic front view of a display panel according to the third embodiment of the invention.

FIG. 7 is a schematic cross-sectional diagram of the display panel of FIG. 6.

FIG. 8 is a schematic front view of a display panel according to the fourth embodiment of the invention.

FIG. 9 is a schematic cross-sectional diagram of the display panel of FIG. 8.

FIG. 10 is a schematic front view of a display panel according to the fifth embodiment of the invention.

### DESCRIPTION OF THE EMBODIMENTS

As used herein, “about”, “approximately”, “essentially”, or “substantially” includes the stated value and the average within an acceptable deviation range for the particular value as determined by one of ordinary skill in the art, taking into account the measurements in question and the specific amount of error associated with the measurements (i.e., limitations of the measurement system). For example, “about” may mean within one or a plurality of standard deviations of the stated value, or for example within +30%, +20%, +15%, +10%, +5%. Furthermore, “about”, “approximately”, “essentially”, or “substantially” used herein may adopt a more acceptable deviation range or standard deviation according to the nature of measurement, cutting, or other properties, instead of one standard deviation applying to all properties.

In the figures, for clarity, the thicknesses of, for example, layers, films, panels, and areas are enlarged. It should be understood that when an element such as a layer, film, areas, or substrate is referred to as being “on” or “connected to” another element, it may be directly on or connected to the other element, or an intermediate element may also be present. On the other hand, when an element is “directly on another device” or “directly connected to” another element, an intermediate element is not present. As used in the present specification, “connected to” may refer to a physical and/or electrical connection. Furthermore, “electrically connected” may mean that other elements are present between two elements.

In addition, relative terms such as “lower” or “bottom” and “upper” or “top” may be used herein to describe the relationship of one element to another element as shown in the figure. It should be understood that relative terms are intended to include different orientations of the device in addition to the orientation shown. For example, if the device in one of the figures is turned over, elements described as being on the “lower” side of other elements would then be oriented on “upper” sides of the other elements. Thus, the exemplary term “lower” may include both an orientation of “lower” and “upper,” depending on the particular orientation of the drawing. Similarly, if the device in one figure is turned over, an element described as “below” other elements or an element “below” is oriented “above” the other elements. Thus, the exemplary term “over” or “under” may include the orientations of above and under.

Exemplary embodiments are described herein with reference to cross section illustrations that are schematic diagrams of idealized embodiments. As such, variations in the shapes of the illustrations as a result, for example, of manufacturing techniques and/or tolerances are to be expected. Thus, embodiments described herein should not be construed as limited to the particular shapes of areas as illustrated herein but are to include deviations in shapes that result, for example, from manufacturing. For example, an area shown or described as flat, may, typically, have rough and/or non-linear features. Additionally, acute corners shown may be rounded. Thus, the areas shown in the figures are schematic in nature and their shapes are not intended to illustrate the precise shape of areas and are not intended to limit the scope of the claims.

Reference will now be made in detail to the exemplary embodiments of the invention, examples of which are illustrated in the accompanying drawings. Wherever possible, the same reference numerals are used in the figures and the descriptions to refer to the same or similar portions.

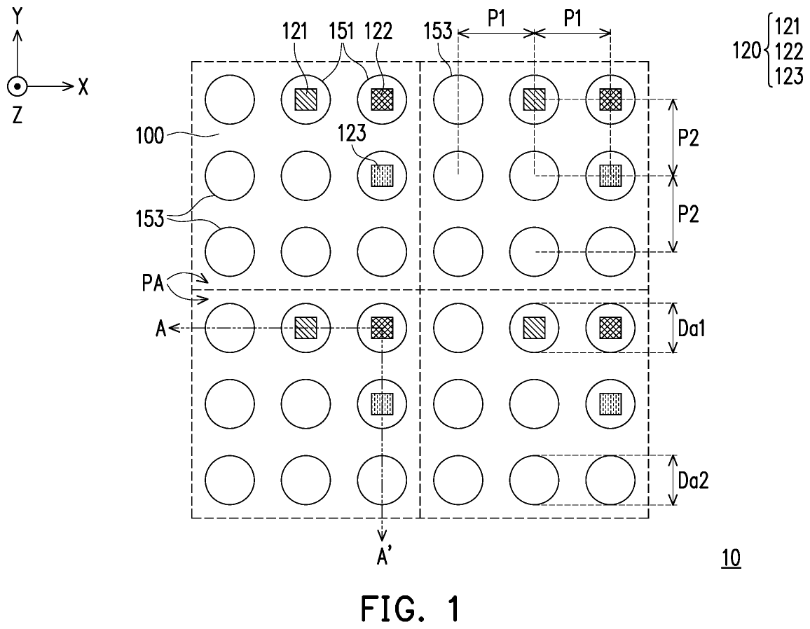

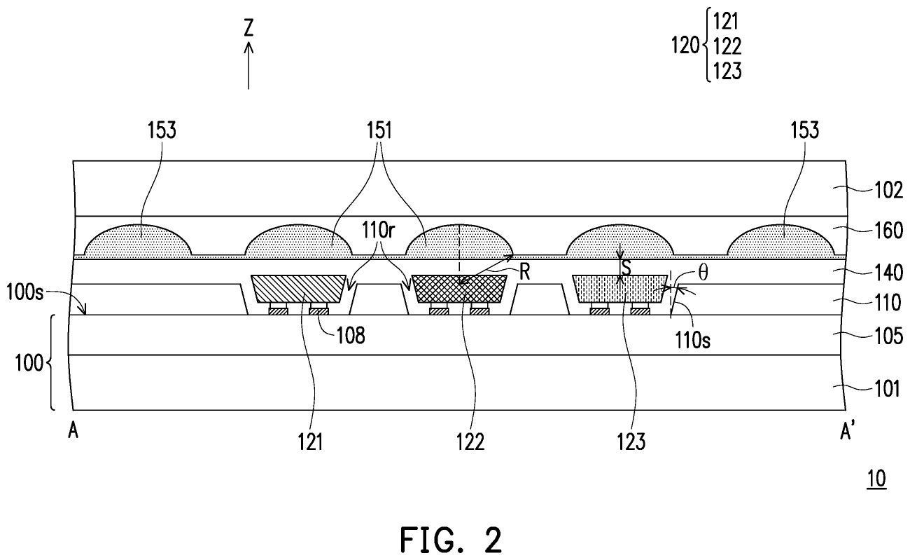

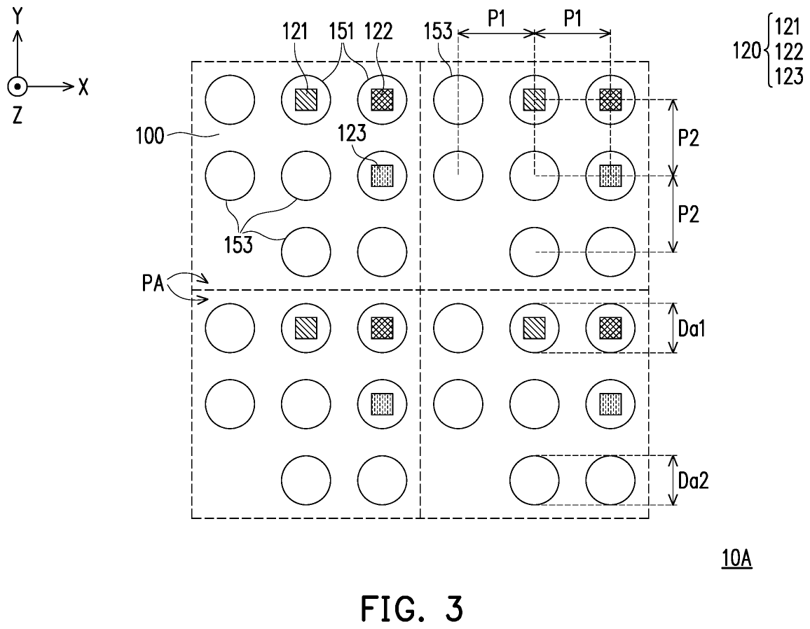

FIG. 1 is a schematic front view of a display panel according to the first embodiment of the invention. FIG. 2 is a schematic cross-sectional diagram of the display panel of FIG. 1. FIG. 3 is a schematic front view of another variant embodiment of the display panel of FIG. 1. FIG. 2 corresponds to the area of section line A-A′ of FIG. 1. For the sake of clarity, FIG. 1 only shows a circuit substrate 100, a microlens 151, a dummy microlens 153, and a light-emitting element 120 of FIG. 2.

Referring to FIG. 1 and FIG. 2, a display panel 10 includes the circuit substrate 100 and a plurality of light-emitting elements 120, a plurality of microlenses 151, and a plurality of dummy microlenses 153 disposed on the circuit substrate 100. The circuit substrate 100 is provided with a plurality of pixel areas PA, and the pixel areas PA may be arranged in an array along a direction X and a direction Y, but not limited thereto.

For example, in the present embodiment, three light-emitting elements 120 with different light emission colors (such as red, green, and blue) may be optionally provided in each of the pixel areas PA, namely a first light-emitting element 121, a second light-emitting element 122, and a third light-emitting element 123, but not limited thereto.

In order to improve the light output efficiency of the light-emitting elements 120, three microlenses 151 are correspondingly provided in each of the pixel areas PA, and the microlenses 151 are overlapped with the first light-emitting element 121, the second light-emitting element 122, and the third light-emitting element 123 respectively. The overlapping relationship here means, for example, that the light-emitting elements 120 and the microlenses 151 are overlapped with each other along the normal direction (e.g., a direction Z) of a surface 100s of the circuit substrate 100. Unless otherwise mentioned below, the overlapping relationship of any two members is defined in the same way, and the overlapping direction of the two is not described again.

In the present embodiment, the first light-emitting element 121 and the second light-emitting element 122 may be arranged along the direction X, the second light-emitting element 122 and the third light-emitting element 123 may be arranged along the direction Y, and the three light-emitting elements 120 and the three microlenses 151 are disposed in an area toward upper right corner in the pixel areas PA (as shown in FIG. 1), but not limited thereto. It is particularly important to note that the plurality of dummy microlenses 153 are provided between the plurality of microlenses 151 in different pixel areas PA, and the dummy microlenses 153 are not overlapped with the plurality of light-emitting elements 120.

For example, the width of each of the pixel areas PA in the direction X may accommodate three light-emitting elements 120 arranged at a pitch P1, and the width in the direction Y may accommodate three light-emitting elements 120 arranged at a pitch P2. That is, the pixel areas PA of the present embodiment may accommodate nine light-emitting elements 120 and nine microlenses 151. However, in the present embodiment, each of the pixel areas PA is not fully arranged with the light-emitting elements 120 in either the direction X or the direction Y, and forms a vacant area of an arrangement range of six light-emitting elements 120 (or six microlenses 151).

Therefore, by arranging the dummy microlenses 153 in the vacant area, the substantial process variation caused by the excessively large surrounding vacant areas in the structural dimensions of the microlenses 151 (such as a radius of curvature R or a circular diameter Da1) may be effectively reduced, thus further improving the overall light output efficiency and uniformity of the display panel 10. In the present embodiment, the configuration number of the dummy microlenses 153 in each of the pixel areas PA is, for example, six, but not limited thereto.

In another variant embodiment, the configuration number of the dummy microlenses 153 in each of the pixel areas PA of the display panel 10A is, for example, five (as shown in FIG. 3), that is, one less dummy microlens 153 is disposed compared to the display panel 10 of FIG. 1. It should be noted that, in a display panel 10A of a variant embodiment, the microlens 151 of each of the overlapped light-emitting element 120 is provided with dummy microlenses 153 at two opposite sides in the direction X or the direction Y. Therefore, even if the vacant area of each of the pixel areas PA is not filled with the dummy microlenses 153, the uniformity of the structural dimensions of the plurality of microlenses 151 may still be improved.

From another perspective, in each of the pixel areas PA, the orthographic projection area of the plurality of dummy microlenses 153 on the circuit substrate 100 is different from the orthographic projection area of the plurality of microlenses 151 on the circuit substrate 100. Preferably, the percentage value of the orthographic projection area of the plurality of microlenses 151 in each of the pixel areas PA on the circuit substrate 100 to the orthographic projection area of the pixel areas PA on the circuit substrate 100 ranges from 0.5% to 30%. The percentage value of the orthographic projection area of the plurality of dummy microlenses 153 in each of the pixel areas PA on the circuit substrate 100 to the orthographic projection area of the pixel areas PA on the circuit substrate 100 ranges from 0.2% to 70%.

In the present embodiment, three microlenses 151 and six dummy microlenses 153 may be arranged in three rows along the direction X at intervals of the pitch P1, and may be arranged in three columns at intervals along the direction Y at intervals of the pitch P2. In particular, the pitch P1 and the pitch P2 may be equal to or different from each other, and are not limited by the invention. Moreover, the microlenses 151 and the dummy microlenses 153 respectively have a first circular diameter Da1 and a second circular diameter Da2, and the first circular diameter Da1 and the second circular diameter Da2 may be optionally the same. From another perspective, the microlenses 151 and the dummy microlenses 153 may each have the same radius of curvature R, but not limited thereto.

Referring to FIG. 2, the circuit substrate 100 may include a substrate 101 and a pixel driving layer 105 disposed on the substrate 101. The pixel driving layer 105 may include a plurality of signal lines (such as scan lines, data lines, or power lines), a plurality of switching elements (such as TFTs), and a plurality of passive elements (such as capacitors) that are not shown. The elements may form a plurality of pixel circuits and be electrically connected to at least one corresponding signal line, but not limited thereto.

In the present embodiment, an isolation structure layer 110 and a plurality of bonding pads 108 may also be provided on the pixel driving layer 105. In detail, the isolation structure layer 110 may have a plurality of grooves 110r, and the plurality of bonding pads 108 are disposed in the grooves 110r and used to bond the plurality of light-emitting elements 120. That is, the plurality of light-emitting elements 120 are also disposed in the grooves 110r of the isolation structure layer 110. It should be noted that, the invention does not limit the number of the light-emitting elements 120 disposed in each of the grooves 110r. In other embodiments, the number of the light-emitting elements 120 in each of the grooves of the isolation structure layer may be a plurality.

The isolation structure layer 110 and the circuit substrate 100 have a slope 110s and a surface 100s defining the grooves 110r, and an included angle θ between the slope 110s and the normal direction (e.g., the direction Z) of the surface 100s may preferably be greater than or equal to 30 degrees and less than or equal to 60 degrees.

Furthermore, the light-emitting elements 120 and the isolation structure layer 110 may be covered with a flat layer 140, and the microlenses 151 and the dummy microlenses 153 are disposed on the flat layer 140. The material of the flat layer 140 may respectively include an inorganic material (such as silicon oxide, silicon nitride, or silicon oxynitride, but not limited thereto), an organic material (for example, polyimide resin, epoxy resin, or acrylic resin, but not limited thereto), or other suitable materials. In the present embodiment, the microlenses 151 may be formed by an organic photoresist material, but not limited thereto.

In the present embodiment, there is a spacing S between a light exit surface ES of the light-emitting elements 120 facing away from the circuit substrate 100 and the overlapped microlenses 151. The spacing S may preferably be greater than or equal to 10 microns and less than or equal to 150 microns. The orthographic projection profile of the microlenses 151 on the flat layer 140 is circular and has the radius of curvature R. The radius of curvature R may preferably be greater than or equal to 10 microns and less than or equal to 50 microns. In a preferred embodiment, the ratio of the spacing S to the radius of curvature R is greater than or equal to 0.1 and less than or equal to 4.

The display panel 10 may also optionally include an encapsulation layer 160 and a light-transmitting substrate 102. The light-transmitting substrate 102 is disposed at a side of the microlenses 151 facing away from the circuit substrate 100. The encapsulation layer 160 is disposed between the light-transmitting substrate 102 and the flat layer 140 and covers the plurality of microlenses 151 and the plurality of dummy microlenses 153. The material of the encapsulation layer 160 includes photoresist, resin, silicone, or other suitable materials. The material of the light-transmitting substrate 102 includes glass, quartz, high molecular polymer (such as polyimide, polycarbonate, polyethylene terephthalate), or other suitable light-transmitting plates.

Some other embodiments are enumerated below to describe the invention in detail, wherein the same components are marked with the same reference numerals, and descriptions of the same technical content is omitted. For the omitted portions, please refer to the above embodiments, which are not be repeated hereafter.

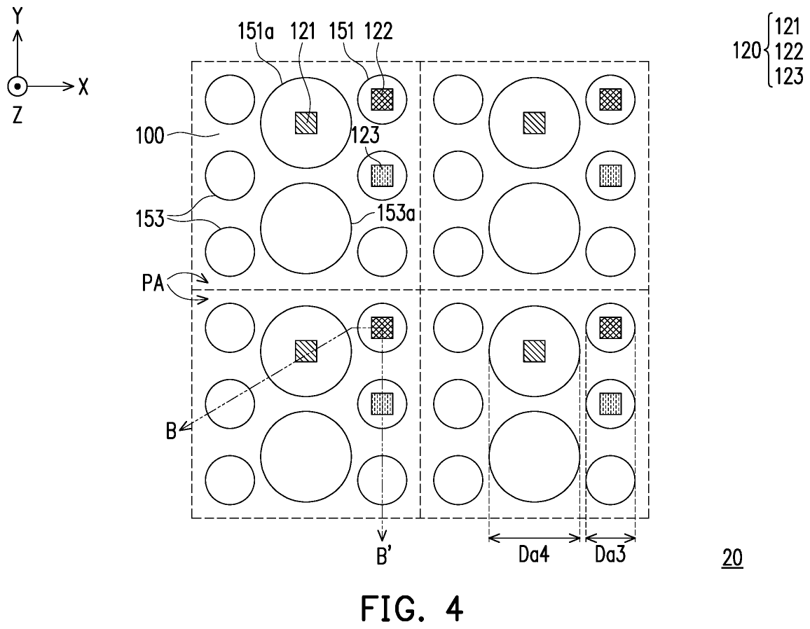

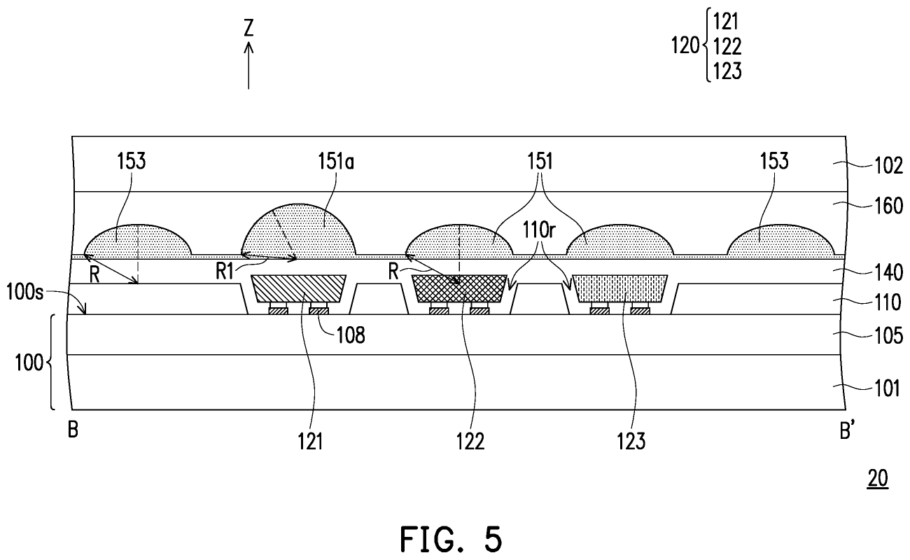

FIG. 4 is a schematic front view of a display panel according to the second embodiment of the invention. FIG. 5 is a schematic cross-sectional diagram of the display panel of FIG. 4. FIG. 5 corresponds to the area of section line B-B′ of FIG. 4. For the sake of clarity, FIG. 4 only shows the circuit substrate 100, the microlens 151, a microlens 151a, the dummy microlens 153, and the light-emitting element 120 of FIG. 5.

Please refer to FIG. 4 and FIG. 5. The difference between a display panel 20 of the present embodiment and the display panel 10 of FIG. 1 is that the structural dimensions of the microlenses and the dummy microlenses are different. For example, in the present embodiment, in the display panel 20, the light emission color of the first light-emitting element 121 is red, the light emission colors of the second light-emitting element 122 and the third light-emitting element 123 are blue and green, and the light output efficiency of the first light-emitting element 121 is less than the light output efficiency of the second light-emitting element 122 and the third light-emitting element 123.

In order to improve the light output efficiency of the first light-emitting element 121, a circular diameter Da4 of the microlens 151a overlapped with the first light-emitting element 121 may be greater than a circular diameter Da3 of the microlens 151 overlapped with the second light-emitting element 122 or the third light-emitting element 123. That is, the orthographic projection area of the microlens 151a on the circuit substrate 100 may be greater than the orthographic projection area of the microlens 151 on the circuit substrate 100.

It should be mentioned that, in the present embodiment, the microlens 151a and one dummy microlens 153a adjacent to each other along the direction Y may have the same circular diameter Da4, and the microlens 151 and the dummy microlens 153 arranged adjacently along the direction Y may have the same circular diameter Da3. That is, in the present embodiment, the circular diameter of each of the orthographic projections of the dummy microlens 153a and the dummy microlens 153 on the circuit substrate 100 may be different. Or, the orthographic projection area of each of the dummy microlens 153a and the dummy microlens 153 on the circuit substrate 100 may be different.

From another perspective, a radius of curvature R1 of the microlens 151a overlapped with the first light-emitting element 121 may be less than the radius of curvature R of the microlens 151 overlapped with the second light-emitting element 122 or the third light-emitting element 123. It should be understood that in another variant embodiment, if the light output efficiencies of the second light-emitting element 122 and the third light-emitting element 123 are different from each other, the radius of curvature of each of the two microlenses respectively overlapped with the second light-emitting element 122 and the third light-emitting element 123 may also be different to compensate for the difference in light output amount between the second light-emitting element 122 and the third light-emitting element 123.

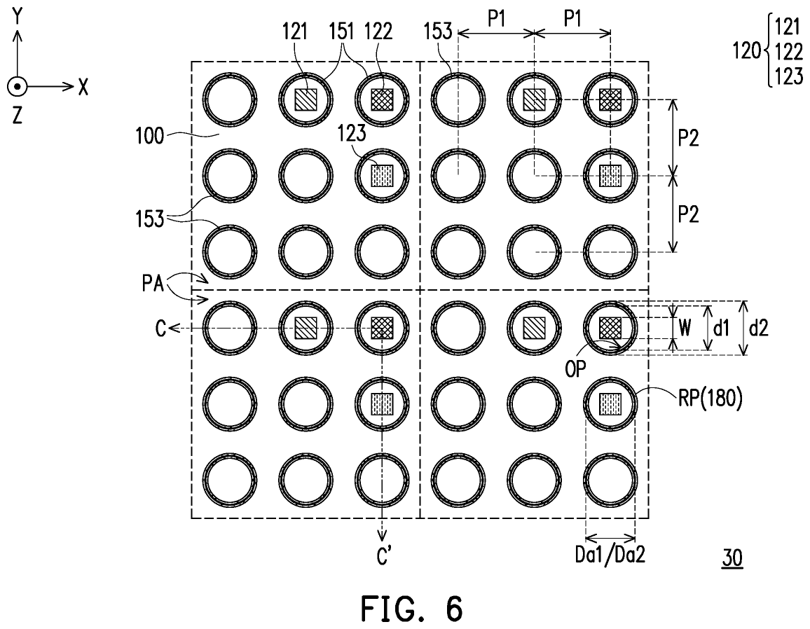

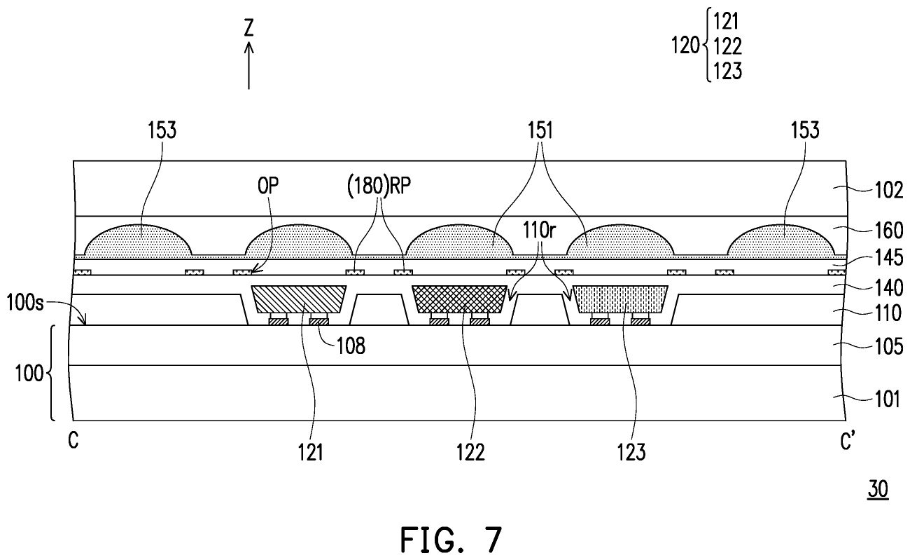

FIG. 6 is a schematic front view of a display panel according to the third embodiment of the invention. FIG. 7 is a schematic cross-sectional diagram of the display panel of FIG. 6. FIG. 7 corresponds to the area of section line C-C′ of FIG. 6. For the sake of clarity, FIG. 6 only shows the circuit substrate 100, the microlens 151, the dummy microlens 153, the light-emitting element 120, and a light-shielding pattern layer 180 of FIG. 7.

Please refer to FIG. 6 and FIG. 7. The difference between a display panel 30 of the present embodiment and the display panel 10 of FIG. 1 and FIG. 2 is that the display panel 30 of the present embodiment further includes the light-shielding pattern layer 180. The light-shielding pattern layer 180 is disposed on the circuit substrate 100 and located between the light-emitting element 120 and the microlens 151.

For example, the light-shielding pattern layer 180 may be disposed on the flat layer 140. Another flat layer 145 is disposed between the light-shielding pattern layer 180 and the microlens 151, and the flat layer 145 covers the light-shielding pattern layer 180, but is not limited thereto. In detail, the light-shielding pattern layer 180 has a plurality of openings OP disposed by overlapping a plurality of microlenses 151 (or a plurality of light-emitting elements 120) and a plurality of dummy microlenses 153. It is particularly noted that in the present embodiment, the light-shielding pattern layer 180 may be a plurality of annular patterns RP defining the plurality of openings OP and separated from each other. The orthographic projections of the annular patterns RP on the circuit substrate 100 respectively surround the orthographic projections of the plurality of microlenses 151 and the plurality of dummy microlenses 153 on the circuit substrate 100.

In the present embodiment, the orthographic projections of the annular patterns RP on the circuit substrate 100 may be annular and have an inner diameter d1 and an outer diameter d2, wherein an inner diameter d1 may be greater than a width w of the light-emitting elements 120 (e.g., the width along the direction X or the direction Y), but not limited thereto. In another embodiment, the inner diameter d1 may also be equal to the width w of the light-emitting elements 120. In a preferred embodiment, the ratio of the outer diameter d2 of the annular patterns RP to the circular diameter Da1 of the microlenses 151 or the circular diameter Da2 of the dummy microlenses 153 is greater than or equal to 1 and less than or equal to 1.5.

In particular, via the arrangement of the light-shielding pattern layer 180, in addition to alleviating the light leakage issue of the light-emitting elements 120 at large angles and the color mixing issue between different light-emitting elements 120, the feature that the plurality of annular patterns RP of the light-shielding pattern layer 180 are structurally separated from each other may also increase the overall light transmittance of the display panel 30 to meet the application requirements of transparent displays.

However, the invention is not limited thereto. In another variant embodiment, the plurality of annular patterns RP of the light-shielding pattern layer may only be disposed overlapped with the microlenses 151, that is, the dummy microlenses 153 may not be provided with the overlapped annular patterns RP. Thereby, the light transmittance of the display panel in the vacant area (that is, the area where the light-emitting elements 120 and the microlenses 151 are not provided) may be further improved.

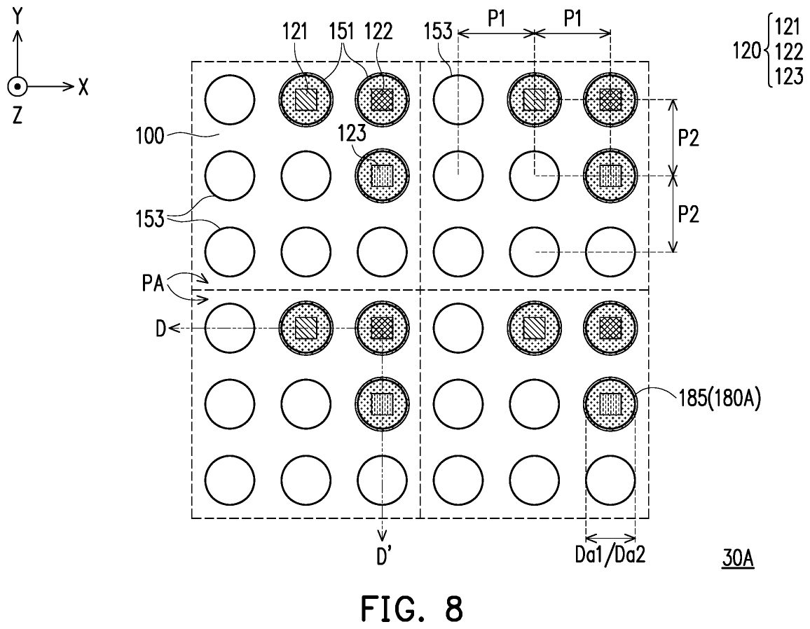

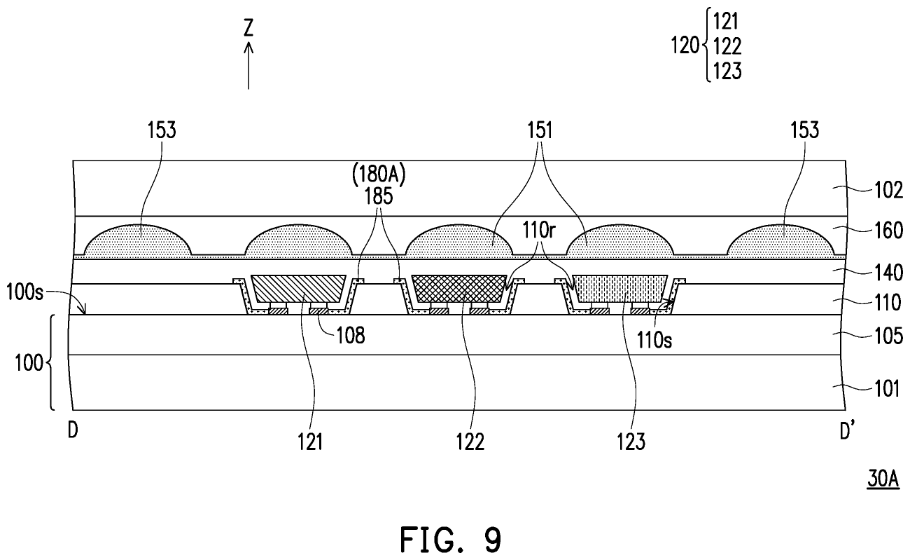

FIG. 8 is a schematic front view of a display panel according to the fourth embodiment of the invention. FIG. 9 is a schematic cross-sectional diagram of the display panel of FIG. 8. FIG. 9 corresponds to the area of section line D-D′ of FIG. 8. For the sake of clarity, FIG. 8 only shows the circuit substrate 100, the microlens 151, the dummy microlens 153, the light-emitting element 120, and a light-shielding pattern layer 180A of FIG. 9.

Please refer to FIG. 8 and FIG. 9. The difference between a display panel 30A of the present embodiment and the display panel 30 of FIG. 6 is that the light-shielding pattern layer is configured in a different manner. Specifically, in the present embodiment, the light-shielding pattern layer 180A of the display panel 30A may be disposed on the isolation structure layer 110 and extended into the plurality of grooves 110r of the isolation structure layer 110.

For example, the light-shielding pattern layer 180A may be formed by a plurality of light-shielding patterns 185 separated from each other, and the light-shielding patterns 185 are only disposed overlapped with the plurality of light-emitting elements 120. That is, the orthographic projections of the plurality of dummy microlenses 153 on the circuit substrate 100 are not overlapped with the orthographic projection of the light-shielding pattern layer 180A on the circuit substrate 100. In this way, the light transmittance of the display panel 30A in the vacant area (that is, the area where the light-emitting elements 120 and the microlenses 151 are not provided) may be significantly improved to meet the application requirements of transparent displays.

In the present embodiment, the orthographic projections of the light-shielding patterns 185 on the circuit substrate 100 may be disk-shaped. More specifically, in addition to covering the slope 110s of the isolation structure layer 110, the light-shielding patterns 185 extended into the grooves 110r of the isolation structure layer 110 also cover a portion of the surface 100s exposed by the isolation structure layer 110 and the bonding pads 108 on the circuit substrate 100 (as shown in FIG. 9). Accordingly, the light leakage issue of the light-emitting elements 120 at large angles and the color mixing issue between different light-emitting elements 120 may be significantly alleviated, thereby improving the display quality of the display panel 30A.

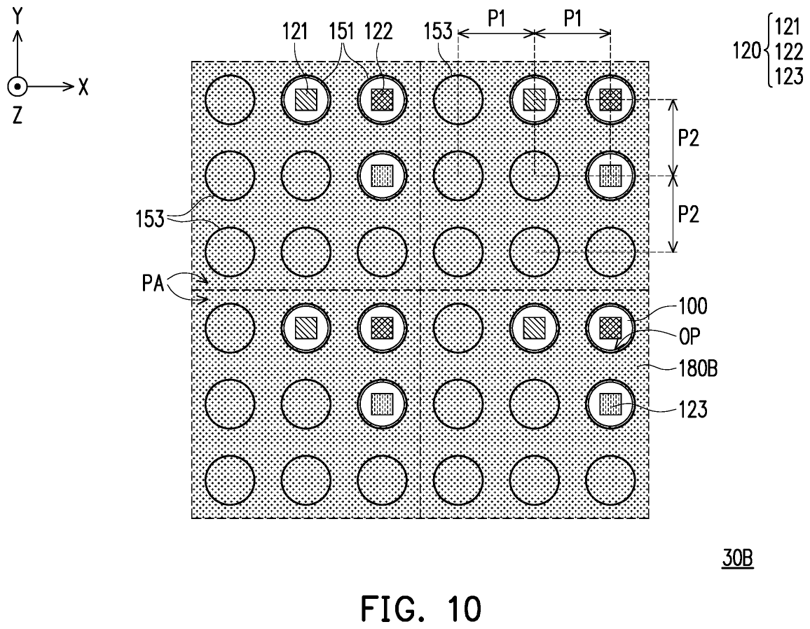

FIG. 10 is a schematic front view of a display panel according to the fifth embodiment of the invention. Please refer to FIG. 10. The difference between a display panel 30B of the present embodiment and the display panel 30 of FIG. 6 is that the light-shielding pattern layer is configured in a different manner. Specifically, in the present embodiment, the plurality of openings OP of the light-shielding pattern layer 180B are only disposed overlapped with the plurality of light-emitting elements 120. From another point of view, the orthographic projections of the plurality of dummy microlenses 153 of the display panel 30B on the circuit substrate 100 are all located within the orthographic projection of the light-shielding pattern layer 180B on the circuit substrate 100. That is, the dummy microlenses 153 are completely overlapped with the light-shielding pattern layer 180B. Accordingly, the light leakage issue of the light-emitting elements 120 at large angles and the color mixing issue between different light-emitting elements 120 may be significantly alleviated, thereby improving the display quality of the display panel 30B.

Based on the above, in the display panel of an embodiment of the invention, the microlenses disposed overlapped with the light-emitting elements may effectively improve the light output efficiency of the light-emitting elements. By disposing the plurality of dummy microlenses in the area around the microlenses without being overlapped with the light-emitting elements, the variation in the curvature radius of the microlenses after the manufacturing process may be effectively reduced.

What is claimed is:

1. A display panel, comprising:
a circuit substrate provided with a plurality of pixel areas;
a plurality of light-emitting elements disposed in each of the pixel areas;
a plurality of microlenses disposed on the circuit substrate and respectively overlapped with the light-emitting elements; and
a plurality of dummy microlenses disposed between the microlenses and not overlapped with the light-emitting elements.

2. The display panel of claim 1, wherein any two adjacent microlenses and dummy microlenses are arranged at a pitch along a direction.

3. The display panel of claim 1, wherein a percentage value of an orthographic projection area of the microlenses on the circuit substrate to an orthographic projection area of any of the pixel areas on the circuit substrate ranges from 0.5% to 30%.

4. The display panel of claim 3, wherein a percentage value of an orthographic projection area of the dummy microlenses on the circuit substrate to the orthographic projection area of any of the pixel areas on the circuit substrate ranges from 0.2% to 70%.

5. The display panel of claim 1, wherein an orthographic projection area of at least a portion of the dummy microlenses on the circuit substrate is different from an orthographic projection area of the microlenses on the circuit substrate.

6. The display panel of claim 1, wherein each of the microlenses has a first circular diameter, each of the dummy microlenses has a second circular diameter, and the first circular diameter is equal to the second circular diameter.

7. The display panel of claim 1, wherein the light-emitting elements comprise a first light-emitting element and a second light-emitting element of different light emission colors, the microlenses comprise a first microlens disposed overlapped with the first light-emitting element and a second microlens disposed overlapped with the second light-emitting element, and an orthographic projection area of the first microlens on the circuit substrate is different from an orthographic projection area of the second microlens on the circuit substrate.

8. The display panel of claim 7, wherein the light emission color of the first light-emitting element is red, the light emission color of the second light-emitting element is green or blue, and a circular diameter of the first microlens is greater than a circular diameter of the second microlens.

9. The display panel of claim 7, wherein the dummy microlenses comprise a first dummy microlens and a second dummy microlens, and an orthographic projection area of the first dummy microlens on the circuit substrate is different from an orthographic projection area of the second dummy microlens on the circuit substrate.

10. The display panel of claim 9, wherein a circular diameter of the first dummy microlens is different from a circular diameter of the second dummy microlens.

11. The display panel of claim 1, further comprising:
a light-shielding pattern layer disposed on the circuit substrate and having a plurality of openings disposed overlapped with the light-emitting elements.

12. The display panel of claim 11, wherein an orthographic projection of the dummy microlenses on the circuit substrate is located within an orthographic projection of the light-shielding pattern layer on the circuit substrate.

13. The display panel of claim 11, wherein the light-shielding pattern layer comprises a plurality of annular patterns defining the openings and separated from each other.

14. The display panel of claim 13, wherein a ratio of an outer diameter of each of the annular patterns to a circular diameter of each of the microlenses is greater than or equal to 1 and less than or equal to 1.5.

15. The display panel of claim 13, wherein an inner diameter of each of the annular patterns is greater than or equal to a width of each of the light-emitting elements.

16. The display panel of claim 11, further comprising:
an isolation structure layer disposed on the circuit substrate and having a plurality of grooves, wherein the light-emitting elements are disposed in the grooves, and the light-shielding pattern layer is disposed on the isolation structure layer and extended into the grooves.

17. The display panel of claim 16, wherein the isolation structure layer and the circuit substrate have a slope and a surface defining each of the grooves, and an included angle between the slope and a normal direction of the surface is greater than or equal to 30 degrees and less than or equal to 60 degrees.

18. The display panel of claim 11, wherein an orthographic projection of the dummy microlenses on the circuit substrate is not overlapped with an orthographic projection of the light-shielding pattern layer on the circuit substrate.

19. The display panel of claim 1, wherein each of the light-emitting elements has a light exit surface facing away from the circuit substrate, there is a spacing between the light exit surface of each of the light-emitting elements and one of the overlapped microlenses, and a ratio of the spacing to a radius of curvature of each of the microlenses is greater than or equal to 0.1 and less than or equal to 4.
